(19) United States
(12) Patent Application Publication
(10) Pub. No.: US 2021/0168312 A1
(43) Pub. Date: Jun. 3, 2021

(54) SEMICONDUCTOR CAPACITOR DEVICES AND METHODS

(71) Applicant: SEMICONDUCTOR COMPONENTS INDUSTRIES, LLC, Phoenix, AZ (US)

(72) Inventors: Raminda U. MADURAWE, Sunnyvale, CA (US); Irfan RAHIM, Milpitas, CA (US)

(73) Assignee: SEMICONDUCTOR COMPONENTS INDUSTRIES, LLC, Phoenix, AZ (US)

(21) Appl. No.: 17/101,981

(22) Filed: Nov. 23, 2020

Related U.S. Application Data
(60) Provisional application No. 62/942,623, filed on Dec. 2, 2019.

(51) Int. Cl. H04N 5/359; H01L 27/146; H04N 5/3745

(52) U.S. Cl. CPC H04N 5/3597; H04N 5/37452; H01L 27/14609

(57) ABSTRACT

Implementations of a pixel may include at least one photodiode coupled with a floating diffusion; a first metal-insulator-metal (MIM) capacitor including a first electrode and a second electrode; and a second MIM capacitor coupled in parallel with the first MIM capacitor, the second MIM capacitor including a first electrode and a second electrode. The first MIM capacitor and second MIM capacitor may be coupled with the floating diffusion.

### CROSS REFERENCE TO RELATED APPLICATIONS

This document claims the benefit of the filing date of U.S. Provisional Patent Application 62/942,623, entitled “Semiconductor Devices and Methods” to Raminda Madurawe which was filed on Dec. 2, 2019, the disclosure of which is hereby incorporated entirely herein by reference.

### BACKGROUND

### 1. Technical Field

Aspects of this document relate generally to electromagnetic radiation sensing devices. More specific implementations involve light image sensors.

### 2. Background

Image sensors are utilized to transform incident electromagnetic radiation into corresponding electrical signals. Various components of an image sensor package include a lid that permits the desired electromagnetic radiation to irradiate the image sensor.

### SUMMARY

Implementations of a pixel may include at least one photodiode coupled with a floating diffusion; a first metal-insulator-metal (MIM) capacitor including a first electrode and a second electrode; and a second MIM capacitor coupled in parallel with the first MIM capacitor, the second MIM capacitor including a first electrode and a second electrode. The first MIM capacitor and second MIM capacitor may be coupled with the floating diffusion.

Implementations of pixels may include one, all, or any of the following:

The first electrode of the first MIM capacitor may be coupled to the second electrode of the second MIM capacitor; and the second electrode of the first MIM capacitor may be coupled to the first electrode of the second MIM capacitor.

The first MIM capacitor and second MIM capacitor may be coupled to permit space-charge drift in the first MIM capacitor and space-charge drift in the second MIM capacitor to cancel.

Pixel implementations may include a high-K dielectric material included between the first electrode and the second electrode of the first MIM capacitor and between the first electrode and the second electrode of the second MIM capacitor.

The high-K dielectric material may include one of a single material layer or multiple material layers.

The high-K dielectric material may be one of hafnium oxide, aluminum oxide, lanthanum oxide, or any combination thereof.

The first electrode of the first MIM capacitor and the first electrode of the second MIM capacitor may be formed at the same time and the second electrode of the first MIM capacitor and the second electrode of the second MIM capacitor may be formed at the same time.

Implementations of a pixel may include at least one photodiode coupled with a floating diffusion; a first metal-insulator-metal (MIM) capacitor including a first electrode and a second electrode; and a second MIM capacitor coupled in series with the first MIM capacitor, the second MIM capacitor including a first electrode and a second electrode. The first MIM capacitor and second MIM capacitor may be coupled with the floating diffusion.

Implementations of a pixel may include one, all, or any of the following:

The first electrode of the first MIM capacitor may be coupled to the first electrode of the second MIM capacitor.

The first MIM capacitor and second MIM capacitor may be coupled to permit space-charge drift in the first MIM capacitor and space-charge drift in the second MIM capacitor to cancel.

The pixel may include a high-K dielectric material included between the first electrode and the second electrode of the first MIM capacitor and between the first electrode and the second electrode of the second MIM capacitor.

The high-K dielectric material may include one of a single material layer or multiple material layers.

The high-K dielectric material may be one of hafnium oxide, aluminum oxide, lanthanum oxide, or any combination thereof.

The first electrode of the first MIM capacitor and the first electrode of the second MIM capacitor may be formed at the same time and the second electrode of the first MIM capacitor and the second electrode of the second MIM capacitor may be formed at the same time.

Implementations of a pixel system may include at least one photodiode coupled with transfer gate coupled with a floating diffusion; a first metal-insulator-metal (MIM) capacitor including a first electrode and a second electrode; and a second MIM capacitor coupled with the first MIM capacitor, the second MIM capacitor including a first electrode and a second electrode. The first MIM capacitor and second MIM capacitor may be coupled with the floating diffusion through a dual conversion gate.

Implementations of a pixel system may include one, all, or any of the following:

The first electrode of the first MIM capacitor may be coupled to the first electrode of the second MIM capacitor.

The first electrode of the first MIM capacitor may be coupled to the second electrode of the second MIM capacitor; and the second electrode of the first MIM capacitor may be coupled to the first electrode of the second MIM capacitor.

The first MIM capacitor and second MIM capacitor may be coupled to permit space-charge drift in the first MIM capacitor and space-charge drift in the second MIM capacitor to cancel.

Implementations of a pixel system may include a high-K dielectric material included between the first electrode and the second electrode of the first MIM capacitor and between the first electrode and the second electrode of the second MIM capacitor.

The floating diffusion may have a capacitance smaller than a sum of a capacitance of the first MIM capacitor and a capacitance of the second MIM capacitor.

Implementations of a pixel system may include at least one photodiode coupled with transfer gate coupled with a floating diffusion; a first metal-insulator-metal (MIM) capacitor including a first electrode and a second electrode; a second MIM capacitor coupled with the first MIM capacitor, the second MIM capacitor including a first electrode and a second electrode; and a dual conversion gate node coupled with the second electrode of the first MIM capacitor and with the first electrode of the second MIM capacitor. The voltage of the dual conversion gate node may be between a voltage of the first electrode of the first MIM capacitor and a voltage of the second electrode of the second MIM capacitor.

Implementations of a pixel system may include one, all, or any of the following:

The voltage of the first electrode of the first MIM capacitor may be maintained at a higher voltage value than a range of possible voltage values of the dual conversion gate node.

The second electrode of the second MIM capacitor may be maintained at a lower voltage value than a range of possible voltage values of the dual conversion gate node.

In various system implementations, opposite rates of change in an electric field in the first MIM capacitor and the second MIM capacitor may minimize an observed charging lag effect or an observed discharging lag effect.

The system may include a high-K dielectric material included between the first electrode and the second electrode of the first MIM capacitor and between the first electrode and the second electrode of the second MIM capacitor.

The floating diffusion may have a capacitance smaller than a sum of a capacitance of the first MIM capacitor and a capacitance of the second MIM capacitor.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a metal-insulator-metal (MIM) capacitor;

FIG. 2 is a schematic of an implementation of a pixel circuit;

FIG. 3 is a cross sectional diagram of an implementation of two MIM capacitors electrically coupled in parallel;

FIG. 4 is a schematic of an implementation of a pixel circuit with two MIM capacitors coupled in parallel;

FIG. 5 is a cross sectional diagram of an implementation of two MIM capacitors electrically coupled in series;

FIG. 6 is a schematic of an implementation of a pixel circuit with two MIM capacitors electrically coupled in series;

FIG. 7 is an electrical equivalent circuit of a MIM capacitor implementation coupled to a time varying voltage source;

FIG. 8 is a schematic of the voltage over time of the MIM capacitor system of FIG. 7; and

FIG. 9 is a schematic of another implementation of a pixel circuit with two MIM capacitors electrical coupled in parallel.

### DESCRIPTION

This disclosure, its aspects and implementations, are not limited to the specific components, assembly procedures or method elements disclosed herein. Many additional components, assembly procedures and/or method elements known in the art consistent with the intended pixel system implementations will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such pixel system implementations, and implementing components and methods, consistent with the intended operation and methods.

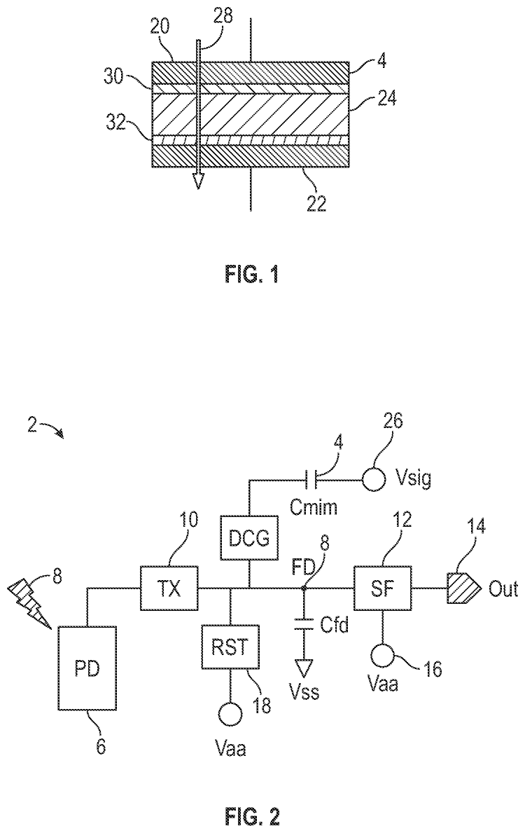

Referring to FIG. 2, a schematic of a pixel circuit (system) 2 is illustrated that includes a metal-insulator-metal (MIM) capacitor 4 with an internal structure like that illustrated in the cross-sectional view in FIG. 1. As illustrated, the circuit 2 includes a photodiode (PD) 6 designed to receive electromagnetic radiation 8 and convert the electromagnetic radiation 8 to electrical charges. The electrical charges accumulate in photodiode 6 (˜10 Kₑ [Coulomb constants] in a particular implementation). In various situations where high dynamic range (HDR) operation of the pixel is desired, more charge than what the photodiode itself can store is needed. Accordingly, in the pixel circuit 2 illustrated, the MIM capacitor 4 is used to store 150 Kₑ or more accumulated charge. In particular implementations, the capacitance of the MIM capacitor may be about 2 femtofarads. During operation, charge from the photodiode 6 is allowed to accumulate in a floating diffusion 8 (which may be a junction diode in various implementations) through operation of transfer gate (TX) 10. When dual conversion gate (DCG) 12 is opened, the charge from the photodiode 6 also is allowed to accumulate in MIM capacitor 4. In the implementation illustrated, the floating diffusion 8 has smaller capacitance than the MIM capacitor 4 (about 0.7 femtofarads). Since the capacitance of the floating diffusion 8 and the capacitance of the MIM capacitor 4 are electrically coupled in parallel, the total capacitance available to store charge during HDR operation of the system illustrated in FIG. 2 is Cfd+Cmim=(2+0.7)=2.7 femtofarads. However, where HDR operation is not desired, then the dual conversion gate 12 remains closed. Source follower transistor (SF) 12 is used to amplify the signal from the floating diffusion using voltage Vaa 16 to generate output signal 14. Reset gate 18 (RST) is used to initialize the floating diffusion and photodiode devices/notes at the start of the charge integration period during exposure to electromagnetic radiation 8. While not shown, a row select transistor (RS) is used to receive the output signal to aid in decoding the output signal and transfer the output signal to the rest of the pixel array circuitry. In the circuit 2 implementation illustrated in FIG. 2, the MIM capacitor 4 is controlled by an external signal voltage Vsig 26 which may be applied in a pulsed configuration in various implementations to allow the user to optimize pixel circuit performance.

Referring to FIG. 1, the structure of the MIM capacitor 4 includes top electrode (second electrode) 20 and bottom electrode (first electrode) 22 with a high dielectric constant material (high-K) material between the electrodes 20, 22. With respect to the value of the dielectric constants used, the capacitance of materials is defined compared to the permittivity of free space. Polarization is the property of any material to have a capacitance larger than free space. Permittivity measures this property of polarization. The dielectric constant K is used as a measure of the relative magnitude of permittivity of a given material compared to the permittivity of free space. A high-K material has more polarization than free space (K=1) and considerably more than a material like air which has a K value of just greater than 1. The higher the polarization of a given material, the greater the K value or capacitance value. A wide variety of polarization types may be observed in the various high-K materials employed in the MIM capacitors utilized in various pixel circuit implementations disclosed herein, such as, by non-limiting example, magnetic polarization, dipole polarization, ferroelectric polarization, space charge polarization, rotational polarization, any combination thereof, or any other polarization type. Many various material types may be employed as high-K dielectric materials in various system implementations disclosed herein, including, by non-limiting example, hafnium oxide (HfO), aluminum oxide (Al₂O₃), lanthanum oxide (La₂O₃), or any other material type with a dielectric constant K greater than 3.9. The use of high-K materials permits a greater storage of charge (i.e., a greater capacitance) within the same electrode surface area. In some implementations, the MIM capacitor may have a capacitance of about 15 femtofarads; in other implementations, the MIM capacitor may have a capacitance of about 60 femtofarads or higher to enable larger dynamic range.

A significant challenge of use of high-K materials in a pixel circuit relates to the shape of the capacitance-voltage curve of the materials. Ideally, the materials would show a constant capacitance as voltage varies. However, the capacitance-voltage curve of a silicon oxide or silicon nitride dielectric material is a small slope linear function of voltage. The coefficient of the voltage function is the non-linearity in the system and is associated with doping depletion of polysilicon or doped silicon capacitor electrodes. Reducing the non-linearity of the voltage function improves the linearity of the pixel circuit system, so the lowest possible non-linearity of the voltage function is desired.

However, the capacitance-voltage curve for MIM capacitors with high-K materials is not linear but is a quadratic function of voltage. The quadratic-voltage coefficient is determined by dipole polarization of the high-K material. The capacitance-voltage curve also can change with applied alternating current (AC) signal frequency. The change can be attributed to the formation of space charge at either top or bottom or both of the capacitor electrodes. The space charge conduction is modulated by frequency, and contributes to loss tangent of the dielectric material. The loss tangent [Tan(δ)] defines a phase shift in space charge conduction compared to the frequency of the applied AC signal. Even for small loss-tangent values for a high-K dielectric, the in-built resistance R is inversely proportional to AC signal frequency, which makes the RC time constant of the pixel circuit containing the high-K capacitor very large. The result is that high-K dielectric materials generally need a long time for space charge developed to dissipate. The effect of this is that high-K capacitors show capacitance drift over time. Other materials, like ferroelectrics also have capacitance-voltage hysteresis that can cause capacitor charge and discharge signal asymmetry. The use of capacitors with time dependent capacitance or capacitance-voltage hysteresis can be undesirable for precision charge integration from a photodiode. Since all forms of polarizable materials have a material property RC time constant that produces demonstrable space charge capacitance response delay and phase-shift compared to applied AC voltage signals, for contact image sensor (CIS) application, the use of high-K materials can be particularly challenging.

The issue of drifting capacitance is also impacted because image sensors generally work in a low frequency domain compared to typical microprocessor clocks. For example, in various image sensor implementations, a typical signal cycle time is within about 10 msec to about 100 msec corresponding with a frequency range of about 10 Hz to about 100 Hz. In various image sensor implementations, a typical reset time for pixel components is in the range>100 nsec to <10 msec (about 100 KHz-about 10 MHz). In a particular pixel circuit implementation like that illustrated in FIG. 2, the reset time is about 700 nsec. For high frame rates, the reset time is likely to remain under about 2-5 msec to maximize signal integration. For example, a video signal having 50 frames per second would operate a 50 Hz, leaving a maximum about 20 msec for integration, read, reset, and other overhead time for the pixel components to operate and reset. Capacitors that have dielectrics where polarization (hence capacitance) is shifted between about 10 Hz-100 Hz signal integration with about 100 KHz-10 MHz reset will cause signal error when signal level changes are experienced and additional errors over time. The effect of the signal error is most noticeable when a scene changes from constant bright to constant dark, or vice versa. This is because the space charge on the high-K capacitor electrodes has to equilibrate between high frequency reset and low frequency signal-capture and the equilibrium point is different for bright (AC signal) versus dark (DC signal) levels. Furthermore, the use of high-K capacitors can result in additional signal error where the space charge capacitance drifts over time.

One specific observable form of a frequency based space charge signal error is lag. Lag is unwanted signal lingering from previous images due to signal value drift. Lag in devices with high-K capacitors is driven by the observed dielectric relaxation of the dielectric material in the capacitors. Discharging lag is observed by a bright image lingering after a sudden change to a dark image, like car head lights showing a gradual fading in the video image after having been turned off. Charging lag is observed when changing a dark image to bright image where the bright signal is observed to slowly get brighter rather than brightening as quickly as it theoretically should. Charging lag is less noticeable than discharging lag. However, in either case the user wants lag-free images. Charging lag occurs when the rate of change of the electric field in the capacitor is rising. Discharging lag occurs when the rate of change of the electric field in the capacitor is falling.

In various pixel circuit implementations employing a single high-K capacitors, lag can be observed. FIG. 1 illustrated how during the application of electric field 28, space charge (SC) 30 is formed in the region of the high-K dielectric 24 adjacent to the second electrode 20 and space charge 32 is formed in the region of the dielectric 24 adjacent to the first electrode 22. Space charge created at the interface of the capacitor electrode and a high-K may be attributable to surface roughness of the electrode. However, the space charge also has been attributed to work function differences between the material of the electrode and the high-K dielectric. While space charge can create lag, because lag is a function of the dielectric relaxation, other effects such as by non-limiting example, charge trapping can contribute to the observed lag as well.

The space charge effects between the second electrode 20 and the first electrode 22 may be different. The two electrodes 20, 22 may not be made of the same material in various pixel circuit implementations. Even where the electrode materials are the same, the interface between first electrode 22 and the high-K dielectric 24 is different from the interface between the second electrode 20 and the dielectric 24. This is in part because the first electrode 22 is exposed to the conditions of the high-K depositing process which are likely modify the surface structure, whereas the material of the top electrode does not undergo those same conditions. This is expected to produce different space charge effects between the two electrodes.

In various implementations of methods of forming MIM capacitors, the bottom electrode (first electrode 22) is deposited first and patterned. Then the high-K dielectric is deposited. In various implementations the high-K dielectric could be a single material layer, such as, by non-limiting example, hafnium oxide, or a series of two or more material layers, such as, by non-limiting example, hafnium oxide and aluminum oxide. After formation of the high-K dielectric, the second electrode 20 is deposited and patterned. In various implementations, after another electrical isolation dielectric deposition step, vias are formed through the materials to form electrical connections with the first electrode 22 and the second electrode 20.

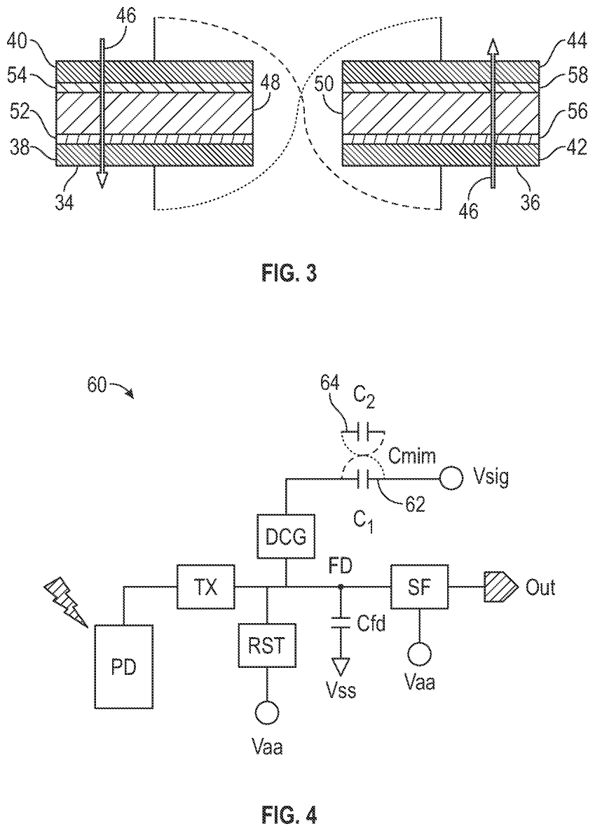

Referring to FIG. 3, two capacitors are illustrated coupled in parallel, a first capacitor 34 and a second capacitor 36. As illustrated, the first electrode 38 of the first capacitor 34 is electrically coupled to the second electrode 44 of the second capacitor 36 and the second electrode 40 of the first capacitor 34 is electrically coupled to the first electrode 42 of the second capacitor 36. As illustrated, because the capacitors are coupled in parallel, each experiences the same electric field 46 during operation, but the orientation of the electric field is equal and opposite in each capacitors 34, 36. As illustrated, under time varying application of voltage typical of operation in a pixel circuit, each capacitor includes a space charge region in the high-K dielectric regions 48, 50 in each of the first capacitor 34 and second capacitor 36, respectively. As illustrated, each electrode includes a separate space charge region, but the sum of the space charges 52, 54 of the first capacitor 34 sees the electric field 46 that is equal but oppositely oriented from the electric field 46 seen by the sum of the space charges 56, 58 of the second capacitor 36. The charges in the first capacitor 34 are moving from the first electrode 38 to the adjacent space charge region 52 while the charges in the second capacitor 36 are moving from the space charge region 56 to first electrode 42 (in opposing directions from capacitor to capacitor). The difference in the electric field polarity experienced by each capacitor and in the movement of charges in each capacitor makes the space charge regions 52, 54 of the first capacitor 34 see charging lag while at the same time the space charge regions 56, 58 see discharging lag. The effect of the parallel coupling serves to substantially cancel the lag resulting in substantially no net lag in either electric field direction.

Where the two capacitors are formed at the same time during semiconductor processing, the lag cancelling effect can be enhanced, as the electrodes and high-K dielectric material are formed simultaneously and where the capacitors are located close to each other, the electrical performance of the capacitors can be as closely correlated as possible. In such implementations, cancellation of all or nearly all observable lag may be achieved in various implementations. In various implementations, the use of coupling of the capacitors may result in mismatch errors that may be very small. In addition to the cancellation of the observed lag, the total capacitance of the capacitors is added because they are coupled in parallel, which for HDR operation is particularly valuable as it allows for the storage of more charge without the deleterious effects of lag.

Referring to FIG. 4, an implementation of a pixel circuit 60 is illustrated. As illustrated, the circuit 60 includes two MIM capacitors (C₁ and C₂) 62, 64 that are coupled in parallel. In this implementation, the first electrodes of each capacitor 62, 64 are coupled to the second electrodes of each capacitor 62, 64. As the space charge regions in each capacitor 62, 64 experience equal and opposite electric fields, an image change from dark to bright or bright to dark will create substantially equal and opposite electric fields in the matched summed space charge regions in each capacitor 62, 64. In this way the summed space charge region in one capacitor experiences a charging lag while the summed space charge region in the other capacitor experiences a discharging lag. While in the foregoing discussions the location of the space charges has been illustrated as being adjacent to both electrodes in both capacitors, the space charges can be present, by non-limiting example, on just one electrode, both electrodes, an interface between two or more dielectric layers within the MIM capacitors, at an interface between two or more dielectric layers in the high-K material, or any combination thereof. In the implementation illustrated in FIG. 4, the various photodiode, transfer gate, dual conversion gate, reset, floating diffusion, and source follower components of the circuit may contain similar structure and/or function similarly to the previously described components with respect to the implementation illustrated in FIG. 2.

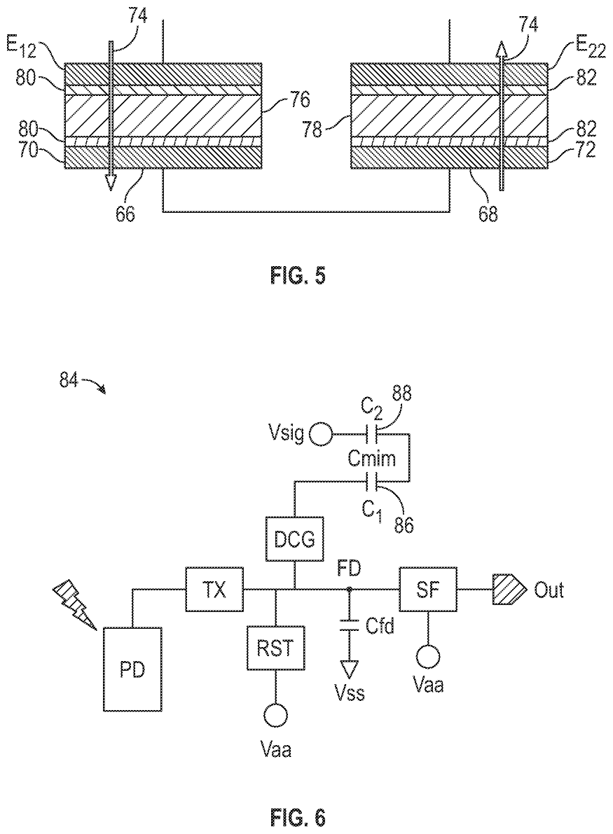

A similar effect on lag can be created if two MIM capacitors are coupled in series rather than in parallel when included in a pixel circuit implementation. Referring to FIG. 5, implementations of two MIM capacitors, a first capacitor 66 and a second capacitor 68 are illustrated electrically coupled together in series, where the first electrode 70 of the first capacitor 66 is electrically coupled to the first electrode 72 of the second capacitor 68. As illustrated, because the first capacitor 66 and second capacitor 68 are coupled in series, equal and opposite electrical fields 74 are experienced by the high-K dielectric material 76, 78 in each capacitor. As illustrated, space charge regions 80, 82 in each of the first capacitor 66 and second capacitor 68, respectively are created by the application of the electrical fields 74. As previously described, the difference in electric field polarity and charge transfer direction between the space charge regions 80, 82 in the first capacitor 66 and second capacitor 68, respectively makes the space charge regions 80 experience charging lag while the space charge regions 82 experience discharging lag. The two space charge region drifts cancel each other to show substantially no or no net lag in either direction of the electric field. While the effect on lag of coupling the capacitors in series is the same or substantially the same as when the capacitors are coupled in parallel, since the net capacitance of the two capacitors is the product of the capacitances of each capacitor divided by the sum of the capacitances, the total capacitance is significantly reduced relative to the parallel case. As previously described, where the MIM capacitors electrically coupled in series are formed simultaneously, the observable lag effect can be substantially reduced or even eliminated in some implementations.

Referring to FIG. 6, an implementation of a pixel circuit 84 is illustrated that includes two capacitors (C₁, C₂) 86, 88 connected in series. As the space charge regions of each capacitor 86, 88 experience equal and opposite electric fields, an image change from dark to bright or bright to dark creates equal and opposite electric fields in the corresponding space charge regions. One pair of space charge regions in capacitor 86 experiences charging lag while the other pair of space charge regions in capacitor 88 experiences discharging lag. The space charge regions can be observed in the series configuration in any of the locations in the structure of each capacitor 86, 88 previously disclosed with respect to the parallel configuration. In the implementation illustrated in FIG. 6, the various photodiode, transfer gate, dual conversion gate, reset, floating diffusion, and source follower components of the circuit may contain similar structure and/or function similarly to the previously described components with respect to the implementation illustrated in FIG. 2.

In various implementations, the behavior of the electrons in the space charge regions can be described as space charge regions trapping charges and de-trapping charges simultaneously, thus canceling second electrode charge imbalances and lag correspondingly.

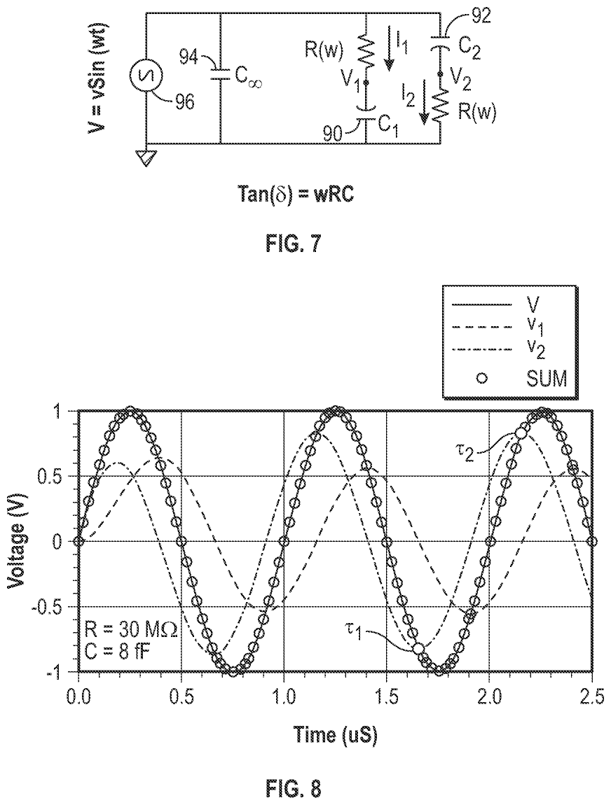

Referring to FIG. 7, a simplified electrical equivalent circuit of two MIM capacitors (C₁, C₂) 90, 92 with high-K materials similar to those illustrated in FIG. 3 or 4 is illustrated with a time varying voltage source V 96 is illustrated. A constant capacitance component of the MIM capacitor structures is illustrated as capacitor (C_{∞}) 94. For the purposes of simplifying the equivalent circuit, just the two capacitors 90, 92 are illustrated, but in other implementations, more than one capacitor could be included. Either of these capacitors may electrically represent either regions 52 and 56 or regions 54 and 58 in FIG. 3. In those implementations where more than two capacitor space-charge pairs are included, the operation of the circuit would be consistent with the principles disclosed herein. In this implementation, in a mixed plate capacitor, the plate nodes can have an opposite phase shift from the voltage signal being applied. At steady state, the voltage v₁ of capacitor 90 is extracted as v₁=v(Cos α)Sin(ωt-α) and the voltage v₂ of capacitor 92 is extracted as v=v(Sin α)Cos(ωt-α). As a result, the current i₁=−i₂ and charge Q₁=−Q₂ and Tan(δ)·0. At all times in the system, there is charging and discharging in the space charge segments/regions of capacitors 90, 92. Since the charging and discharging of the space charge regions is symmetric, the resulting charging and discharging lag cancels out. FIG. 8 is a graph of the time-varying voltage of the system along with the time varying voltage v₁ and v₂ experienced by each capacitor 90, 92. As can be observed by inspecting the location of the summed points on the graph in FIG. 8, the sum of voltage v₁ and v₂ matches the applied voltage of the system in both voltage and time location (phase), meaning that substantially all voltage lag effects caused by the non-linear high-K capacitor material have canceled each other out.

While the previous discussion involves a particular structural configuration of a pixel configuration designed to affect the effect of space charge on the dielectric relaxation of a high-K capacitor, other pixel circuit implementations like those disclosed herein may be used where space charge is not the dominant or not the cause of the dielectric relaxation driving the observed lag. In other implementations, the dielectric relaxation behavior driving the observed lag behavior may need to be handled using a different structural configuration for the MIM capacitors.

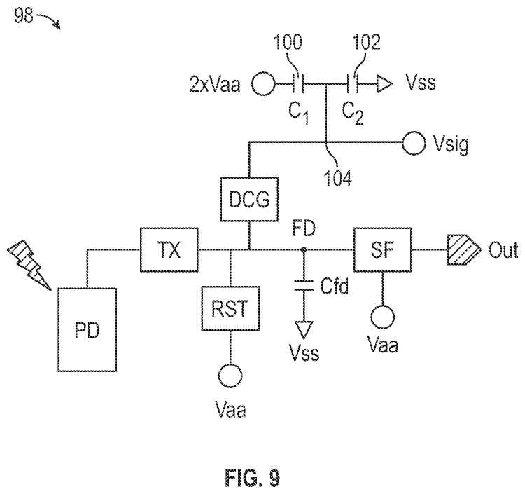

Referring to FIG. 9, a schematic of another implementation of a pixel circuit 98 with two MIM capacitors which may be any of this disclosed herein is illustrated. Here, the bottom plate (second electrode) of first capacitor C1 102 is connected in with dual conversion gate (DCG) node 104 with the top plate (first electrode) of second capacitor C2 100. The DCG node 104 has a voltage value equal to the voltage applied to Vsig when the DCG opens. This voltage value of the DCG node 104, therefore, varies depending on whether the DCG is open or not. As illustrated in FIG. 9, the top plate (first electrode) of first capacitor C1 100 is pinned at a voltage that is twice Vaa while the bottom plate (second electrode) of second capacitor C2 102 is attached to Vss, which is this case is set to ground. Initially, when the DCG is closed, the value of the voltage of the DCG node 104 is located between the value of the voltage of the first electrode of capacitor C1 and the voltage of the second electrode of capacitor C2. This is because the second electrode of Cl and the first electrode of C2 are electrically common with the DCG node 104. When the DCG opens, because the value of the first electrode of first capacitor C1 100 is pinned at twice Vaa, the value of the voltage of the DCG node 104 now changes to a new value that is still located between the voltage value of the first electrode of the first capacitor C1 and the voltage value of the second electrode of second capacitor C2. Because of physical arrangement, the change in the electric field in capacitor C1 100 is directly proportional of the rate of change of the electric field in capacitor C2 102. In some implementations, the rates of change in the electric field may be the same (equal and opposite). In other implementations, however, the rates of change are different. As a result in proportional rates of change in the electric field, any charging lag in capacitor C2 102 is canceled by or substantially canceled by any discharging lag in capacitor C1 100. The result is that no or substantially no charging lag or discharging lag is observed in the image produced by the image sensor device. While the use of a twice Vaa voltage value for the first electrode of Cl and ground for the second electrode of C2 are illustrated in the implementation in FIG. 9, any voltage values could be used provided the relationship that the voltage value of first electrode of C1>range of voltages of DCG node>voltage value of second electrode of C1 is maintained.

In situations where dielectric relaxation of the high-K materials in the MIM capacitors is driven partially or substantially by factors other than space charge effects (and in situations where space charge dominates), the structural configuration of the MIM capacitors 100, 102 illustrated in FIG. 9 may most successfully eliminate observed lag. This is because the structural arrangement of the MIM capacitors 100, 102 relies on equalizing/proportionalizing the rates of change of the electrical fields in each of the capacitors 100, 102 rather than orienting the directions of electric field lines to be in equal and opposite directions, as in the space charge-focused arrangements illustrated in FIGS. 4 and 6. In this way, the arrangement of the MIM capacitors in FIG. 9 may provide a more generally applicable solution to the effect of lag caused by dielectric relaxation effects caused by various electronic effects of high-K materials rather than the arrangements in FIGS. 4 and 6.

In places where the description above refers to particular implementations of pixel systems and implementing components, sub-components, methods and sub-methods, it should be readily apparent that a number of modifications may be made without departing from the spirit thereof and that these implementations, implementing components, sub-components, methods and sub-methods may be applied to other pixel system implementations.

What is claimed is:

1. A pixel comprising:
at least one photodiode coupled with a floating diffusion;
a first metal-insulator-metal (MIM) capacitor comprising a first electrode and a second electrode; and
a second MIM capacitor coupled in parallel with the first MIM capacitor, the second MIM capacitor comprising a first electrode and a second electrode;
wherein the first MIM capacitor and second MIM capacitor are coupled with the floating diffusion.

2. The pixel of claim 1, wherein:
the first electrode of the first MIM capacitor is coupled to the second electrode of the second MIM capacitor; and
the second electrode of the first MIM capacitor is coupled to the first electrode of the second MIM capacitor.

3. The pixel of claim 2, wherein the first MIM capacitor and second MIM capacitor are coupled to permit space-charge drift in the first MIM capacitor and space-charge drift in the second MIM capacitor to cancel.

4. The pixel of claim 1, further comprising a high-K dielectric material comprised between the first electrode and the second electrode of the first MIM capacitor and between the first electrode and the second electrode of the second MIM capacitor.

5. The pixel of claim 4, wherein the high-K dielectric material comprises one of a single material layer or multiple material layers.

6. The pixel of claim 4, wherein the high-K dielectric material is one of hafnium oxide, aluminum oxide, lanthanum oxide, or any combination thereof.

7. The pixel of claim 1, wherein the first electrode of the first MIM capacitor and the first electrode of the second MIM capacitor are formed at the same time and the second electrode of the first MIM capacitor and the second electrode of the second MIM capacitor are formed at the same time.

8. A pixel comprising:
at least one photodiode coupled with a floating diffusion;
a first metal-insulator-metal (MIM) capacitor comprising a first electrode and a second electrode; and
a second MIM capacitor coupled in series with the first MIM capacitor, the second MIM capacitor comprising a first electrode and a second electrode;
wherein the first MIM capacitor and second MIM capacitor are coupled with the floating diffusion.

9. The pixel of claim 8, wherein the first electrode of the first MIM capacitor is coupled to the first electrode of the second MIM capacitor.

10. The pixel of claim 9, wherein the first MIM capacitor and second MIM capacitor are coupled to permit space-charge drift in the first MIM capacitor and space-charge drift in the second MIM capacitor to cancel.

11. The pixel of claim 8, further comprising a high-K dielectric material comprised between the first electrode and the second electrode of the first MIM capacitor and between the first electrode and the second electrode of the second MIM capacitor.

12. The pixel of claim 11, wherein the high-K dielectric material comprises one of a single material layer or multiple material layers.

13. The pixel of claim 11, wherein the high-K dielectric material is one of hafnium oxide, aluminum oxide, lanthanum oxide, or any combination thereof.

14. The pixel of claim 8, wherein the first electrode of the first MIM capacitor and the first electrode of the second MIM capacitor are formed at the same time and the second electrode of the first MIM capacitor and the second electrode of the second MIM capacitor are formed at the same time.

15. A pixel system comprising:
at least one photodiode coupled with transfer gate coupled with a floating diffusion;
a first metal-insulator-metal (MIM) capacitor comprising a first electrode and a second electrode;
a second MIM capacitor coupled with the first MIM capacitor, the second MIM capacitor comprising a first electrode and a second electrode; and
a dual conversion gate node coupled with the second electrode of the first MIM capacitor and with the first electrode of the second MIM capacitor;
wherein a voltage of the dual conversion gate node is between a voltage of the first electrode of the first MIM capacitor and a voltage of the second electrode of the second MIM capacitor.

16. The system of claim 15, wherein the voltage of the first electrode of the first MIM capacitor is maintained at a higher voltage value than a range of possible voltage values of the dual conversion gate node.

17. The system of claim 15, wherein:
the second electrode of the second MIM capacitor is maintained at a lower voltage value than a range of possible voltage values of the dual conversion gate node.

18. The system of claim 15, wherein opposite rates of change in an electric field in the first MIM capacitor and the second MIM capacitor to minimize an observed charging lag effect or an observed discharging lag effect.

19. The system of claim 15, further comprising a high-K dielectric material comprised between the first electrode and the second electrode of the first MIM capacitor and between the first electrode and the second electrode of the second MIM capacitor.

20. The system of claim 15, wherein the floating diffusion has a capacitance smaller than a sum of a capacitance of the first MIM capacitor and a capacitance of the second MIM capacitor.
